(19) United States
(12) Patent Application Publication
(10) Pub. No.: US 2009/0197494 A1
(43) Pub. Date: Aug. 6, 2009

(54) Anti-microbial fabric and method for producing the same

(76) Inventors: Chia-Yuan Chang, Taipei County (TW); Chia-Hung Hsu, Hsinchu County (TW)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/155,988

(22) Filed: Jun. 12, 2008

(30) Foreign Application Priority Data
Jan. 31, 2008 (TW) 097103727
Apr. 24, 2008 (TW) 097115023

(51) Int. Cl. C23C 14/14; D03D 15/00; B32B 15/14

(52) U.S. Cl. 442/230; 204/192.12; 204/192.15; 442/379; 442/317

(57) ABSTRACT

A method for producing an anti-microbial fabric includes: (a) depositing anti-microbial metal-based clusters on an outer surface of a fabric substrate by sputtering a metal-based target material which possesses anti-microbial activity and which is prone to oxidation upon air exposure; and (b) depositing oxidation-resistant metal-based clusters on the outer surface of the fabric substrate by sputtering an oxidation-resistant metal-based target material in such an amount as to enable the oxidation-resistant metal-based clusters to partially cover the anti-microbial metal-based clusters so as to permit exposure of at least a part of one of the anti-microbial metal-based clusters. An anti-microbial fabric produced thereby is also disclosed.

### CROSS-REFERENCE TO RELATED APPLICATION

This application claims priority of Taiwanese application no. 97103727, filed on Jan. 31, 2008, and Taiwanese application no. 97115023, filed on Apr. 24, 2008.

### BACKGROUND OF THE INVENTION

1. Field of the Invention

This invention relates to an anti-microbial fabric and a method for producing the same, more particularly to an anti-microbial fabric having anti-microbial metal-based clusters and oxidation-resistant metal-based clusters, and a method for producing the same.

2. Description of the Related Art

Anti-microbial fabrics are generally produced using a wet spinning method. For example, U.S. Pat. No. 6,524,508 discloses a process for preparing chitosan-containing acrylic fibers, which includes the steps of: preparing acrylic fibers using a wet spinning procedure; immersing a yarn of the acrylic fibers in an aqueous acidic chitosan solution; and densifying the yarn of the acrylic fibers with drying. JP 9059820 discloses a method for producing anti-microbial fibers, which includes the steps of: dispersing TiO₂ in an organic solvent so as to form a dispersion, and adding the dispersion into an acrylonitrile copolymer solution, followed by a spinning process. Moreover, TW I283717 discloses a method for preparing silver-containing fibers, which includes: dispersing a silver salt compound in a dispersion so as to form a nano-silver solution, and adding polymer resin into the nano-silver solution, followed by a wet spinning process.

Recently, depositing procedures are employed to manufacture anti-microbial fabrics. US patent application publication no. 2006/0134390 discloses a method for producing durable anti-microbial multi-filament yarns, which includes: providing a knitted fabric; forming an inorganic anti-microbial material, e.g., Ag, on at least one surface of the knitted fabric by a PVD method; and performing a deknitted process for deknitting the knitted fabric to an anti-microbial multi-filament yarn.

When silver (Ag) is used as an anti-microbial material in an anti-microbial fabric, the fabric is liable to color-change due to oxidation, vulcanization, and light-exposure of the silver material therein. To avoid color-change, a chemical anti-oxidant coating is generally applied to the fabric. However, such chemical coating is likely to induce skin allergy and environmental problems.

### SUMMARY OF THE INVENTION

Therefore, an object of the present invention is to provide an anti-microbial fabric and a method for producing the same, that can overcome the aforesaid drawbacks of the prior art.

According to one aspect of this invention, a method for producing an anti-microbial fabric includes:

(a) depositing anti-microbial metal-based clusters on an outer surface of a fabric substrate by sputtering a metal-based target material which possesses anti-microbial activity and which is prone to oxidation upon air exposure; and

(b) depositing oxidation-resistant metal-based clusters on the outer surface of the fabric substrate by sputtering an oxidation-resistant metal-based target material in such an amount as to enable the oxidation-resistant metal-based clusters to partially cover the anti-microbial metal-based clusters so as to permit exposure of at least a part of one of the anti-microbial metal-based clusters.

According to another aspect of this invention, an anti-microbial fabric is prepared by a process comprising the following steps:

(a) depositing anti-microbial metal-based clusters on an outer surface of a fabric substrate by sputtering a metal-based target material which possesses anti-microbial activity and which is prone to oxidation upon air exposure; and

(b) depositing oxidation-resistant metal-based clusters on the outer surface of the fabric substrate by sputtering an oxidation-resistant metal-based target material in such an amount as to enable the oxidation-resistant metal-based clusters to partially cover the anti-microbial metal-based clusters so as to permit exposure of at least a part of one of the anti-microbial metal-based clusters.

### BRIEF DESCRIPTION OF THE DRAWING

Other features and advantages of the present invention will become apparent in the following detailed description of the preferred embodiments of this invention, with reference to the accompanying drawing, in which:

FIG. 1 is a fragmentary schematic view of the preferred embodiment of an anti-microbial fabric according to this invention.

### DETAILED DESCRIPTION OF THE PREFERRED EMBODIMENTS

### Definition:

In this invention, by the term “oxidation,” it is meant, in a broad sense, that a chemical reaction involves an increase in oxidation number, or a loss of electrons by a molecule, atom, or ion.

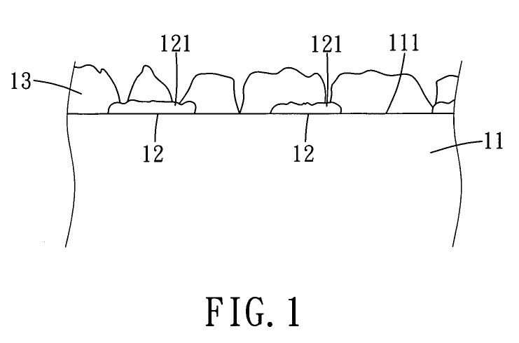

Referring to FIG. 1, the preferred embodiment of an anti-microbial fabric according to the present invention is shown to include: a fabric substrate 11 having an outer surface 111; a plurality of anti-microbial metal-based clusters 12 deposited on the outer surface 11 of the fabric substrate 11; and a plurality of oxidation-resistant metal-based clusters 13 deposited on the outer surface 111 of the fabric substrate 11 and the anti-microbial metal-based clusters 12. In this embodiment, the oxidation-resistant metal-based clusters 13 are not completely superimposed on the anti-microbial metal-based clusters 12 so that at least a part 121 of one of the anti-microbial metal-based clusters 12 is not overlaid by the oxidation-resistant metal-based clusters 13. With the oxidation-resistant metal-based clusters 13 partially covering the anti-microbial metal-based clusters 12, oxidation of the anti-microbial metal-based clusters 12 can be diminished. At the same time, the exposed parts 121 of the anti-microbial metal-based clusters 12 can still provide an anti-microbial effect.

Preferably, the anti-microbial metal-based clusters 12 are silver clusters, and are present in an amount ranging from 10 to 2,000 ppm.

Preferably, the oxidation-resistant metal-based clusters 13 are composed of a metal of Ti, Au, Pd, or Pt, and have an average thickness ranging from 50 to 500 Å.

The anti-microbial fabric of this invention is prepared by the following steps using a roll-to-roll type magnetron sputtering apparatus (not shown):

(a) depositing anti-microbial metal-based clusters 12 on an outer surface 111 of a fabric substrate 11 by magnetron sputtering a metal-based target material which possesses anti-microbial activity and which is prone to oxidation upon air exposure; and

(b) depositing oxidation-resistant metal-based clusters 13 on the outer surface 111 of the fabric substrate 11 by magnetron sputtering an oxidation-resistant metal-based target material in such an amount as to enable the oxidation-resistant metal-based clusters 13 to partially cover the anti-microbial metal-based clusters 12 so as to permit exposure of at least a part 121 of one of the anti-microbial metal-based clusters 12.

Preferably, step (a) is carried out under an argon gas working pressure of 2×10⁻³ to 8×10⁻³ torr and a power density of 0.2 to 10 w/cm². More preferably, the argon gas working pressure ranges from 3×10⁻³ to 6×10⁻³ torr.

Preferably, step (b) is carried out under an argon gas working pressure of 2×10⁻³ to 8×10⁻³ torr and a power density of 2 to 17 w/cm². More preferably, the argon gas working pressure ranges from 3×10⁻³ to 6×10⁻³ torr.

Preferably, examples of the fabric substrate 11 include a non-woven fabric and a woven fabric.

In an embodiment of this invention, silver is employed as the metal-based target material to sputter silver atoms on the outer surface 111 of the fabric substrate 11 so as to form the nano-scale silver clusters 12.

It should be noted that the amount of the anti-microbial metal-based clusters 12 can vary. Considering factors, such as, costs, working pressures, and the desired anti-microbial effect, the amount of the anti-microbial metal-based clusters 12 preferably ranges from 10 to 2,000 ppm.

Preferably, the metal-based target material for the oxidation-resistant metal-based clusters 13 is composed of a metal, e.g., Ti, Au, Pd, and Pt, or alloys thereof so that the resultant oxidation-resistant metal-based clusters 13 are composed of the metal, e.g., Ti, Au, Pd, or Pt. Each of the oxidation-resistant metal-based clusters 13 has an average thickness ranging from 50 to 500 Å.

Considering the material and the thickness range of the oxidation-resistant metal-based clusters 13, the power density is designed to be between 2 and 17 w/cm² when depositing the oxidation-resistant metal-based clusters 13 on the outer surface 111 of the fabric substrate 11.

### EXAMPLES

### Example 1

A roll of 30 gsm melt-blown non-woven fabric 11 (white color) was set in a roll-to-roll type magnetron sputtering apparatus (not shown), and was transferred by drive motors (not shown) at a transferring speed of 12 m/min. The melt-blown non-woven fabric 11 was coated with 100 ppm silver clusters 12 by magnetron sputtering silver on an outer surface 111 of the non-woven fabric 11 under an argon gas working pressure of 2×10⁻³ torr, a power density of 0.3 w/cm², and a sputtering rate of 12 m/min. The silver-coated non-woven fabric 11 was subsequently coated with titanium clusters 13 having an average thickness ranging from 100 to 150 Å by magnetron sputtering titanium on the outer surface 111 of the non-woven fabric 11 and on the silver clusters 12 under an argon gas working pressure of 2×10⁻³ torr, a power density of 5 w/cm², and a sputtering rate of 12m/min. The titanium clusters 13 did not completely cover the silver clusters 12, so that parts 121 of the silver clusters 12 were exposed from the titanium clusters 13. The anti-microbial fabric thus obtained was subjected to anti-microbial tests using AATCC Test Method 100, in which the anti-microbial activity (R %) of the fabric against Staphylococcus aureus ATCC 6538, Escherichia coli ATCC 8739, Klebsiella pneumoniae ATCC 4352, Pseudomonas aeruginosa ATCC 9027, and Candida albicans ATCC 10231 was determined. The test results are shown in Table 1.

### Example 2

A roll of 50 Denier knitted polyester fabric 11 (light blue) was set in a roll-to-roll type magnetron sputtering apparatus (not shown), and was transferred by drive motors (not shown) at a transferring speed of 12 m/min. The polyester fabric 11 was coated with 100 ppm silver clusters 12 by magnetron sputtering silver on an outer surface 111 of the polyester fabric 11 under an argon gas working pressure of 3.75×10⁻³ torr, a power density of 0.3 w/cm², and a sputtering rate of 12 m/min. The silver-coated polyester fabric 11 was subsequently coated with titanium clusters 13 having an average thickness ranging from 100 to 150 Å by magnetron sputtering titanium on the outer surface 111 of the polyester fabric 11 and on the silver clusters 12 under an argon gas working pressure of 3.75×10⁻³ torr, a power density of 5 w/cm², and a sputtering rate of 12 m/min. The titanium clusters 13 did not completely cover the silver clusters 12, so that parts 121 of the silver clusters 12 were exposed from the titanium clusters 13. The anti-microbial fabric thus obtained was subjected to an anti-microbial test using AATCC Test Method 100, in which the anti-microbial activity (R %) of the fabric against Staphylococcus aureus ATCC 6538 was determined. The test results are shown in Table 1.

### Example 3

A roll of 30 gsm melt-blown non-woven fabric 11 (white color) was set in a roll-to-roll type magnetron sputtering apparatus (not shown), and was transferred by drive motors (not shown) at a transferring speed of 12 m/min. The melt-blown non-woven fabric 11 was coated with 300 ppm silver clusters 12 by magnetron sputtering silver on an outer surface 111 of the non-woven fabric 11 under an argon gas working pressure of 6×10⁻³ torr, a power density of 1.5 w/cm², and a sputtering rate of 12 m/min. The silver-coated non-woven fabric 11 was subsequently coated with titanium clusters 13 having an average thickness ranging from 200 to 250 Å by magnetron sputtering titanium on the outer surface 111 of the non-woven fabric 11 and on the silver clusters 12 under an argon gas working pressure of 6×10⁻³ torr, a power density of 8 w/cm², and a sputtering rate of 12 m/min. The titanium clusters 13 did not completely cover the silver clusters 12, so that parts 121 of the silver clusters 12 were exposed from the titanium clusters 13. The anti-microbial fabric thus obtained was subjected to an anti-microbial test using AATCC Test Method 100, in which the anti-microbial activity (R %) of the fabric against methicillin resistant Staphylococcus aureus ATCC 33591 was determined. The test results are shown in Table 1.

### Example 4

A roll of 30 gsm melt-blown non-woven fabric 11 (white color) was set in a roll-to-roll type magnetron sputtering apparatus (not shown), and was transferred by drive motors (not shown) at a transferring speed of 12 m/min. The melt-blown non-woven fabric 11 was coated with 200 ppm silver clusters 12 by magnetron sputtering silver on an outer surface 111 of the non-woven fabric 11 under an argon gas working pressure of 8×10⁻³ torr, a power density of 0.5 w/cm², and a sputtering rate of 12 m/min. The silver-coated non-woven fabric 11 was subsequently coated with titanium clusters 13 having an average thickness ranging from 200 to 250 Å by magnetron sputtering titanium on the outer surface 111 of the non-woven fabric 11 and on the silver clusters 12 under an argon gas working pressure of 8×10⁻³ torr, a power density of 8 w/cm², and a sputtering rate of 12 m/min. The titanium clusters 13 did not completely cover the silver clusters 12, so that parts 121 of the silver clusters 12 were exposed from the titanium clusters 13. The anti-microbial fabric thus obtained was subjected to anti-microbial test using AATCC Test Method 100, in which anti-microbial activity (R %) of the fabric against Staphylococcus aureus ATCC 6538 was determined. The test results are shown in Table 1.

TABLE 1

| | | Reduction | | | | Reduction | Reduction |
|---|---|---|---|---|---|---|---|
| | Reduction | (R %) for | Reduction | Reduction | Reduction | (R %) for | (R %) for |
| | (R %) for | ATCC | (R %) for | (R %) for | (R %) for | ATCC | ATCC |
| | ATCC 6538¹ | 33591¹ | ATCC 8739¹ | ATCC 4352¹ | ATCC 9027¹ | 10231¹ | 10231 (30 min)² |
| Example 1 | 99.9 | — | 99.9 | 99.9 | 99.9 | 99.9 | 95.2 |
| Example 2 | 99.9 | — | — | — | — | — | — |
| Example 3 | — | 99.9 | — | — | — | — | — |
| Example 4 | 99.9 | — | — | — | — | — | — |

—: “not tested”
¹R % = (bacteria counts at 0 hr incubating time − bacteria counts at 24 hr incubating time)/bacteria counts at 0 hr incubating time × 100
²R % = (bacteria counts at 0 min incubating time − bacteria counts at 30 min incubating time)/bacteria counts at 0 min incubating time × 100

As shown in Table 1, the anti-microbial activity (R %) of the anti-microbial fabrics of this invention against all the tested bacteria can be up to 99.9% at 24 hour incubating time, and the anti-microbial fabric of Example 1 still exhibits 95.2% anti-microbial activity against Candida albicans ATCC 10231 at 30 min incubating time. Therefore, although the silver clusters 12 were partly covered by the titanium clusters 13, which prevented oxidation thereof, the exposed silver clusters 121 still provided good anti-microbial activity.

As illustrated, by sputtering an oxidation-resistant metal-based target material on the outer surface 111 of the fabric substrate 11 to form the oxidation-resistant metal-based clusters 13 that cover a major part of the anti-microbial metal-based clusters 12 while exposing a minor part thereof, the anti-microbial fabric according to the present invention can provide good anti-microbial activity, and oxidation of the anti-microbial metal-based clusters 12 therein can be diminished.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A method for producing an anti-microbial fabric, comprising:
(a) depositing anti-microbial metal-based clusters on an outer surface of a fabric substrate by sputtering a metal-based target material which possesses anti-microbial activity and which is prone to oxidation upon air exposure; and
(b) depositing oxidation-resistant metal-based clusters on the outer surface of the fabric substrate by sputtering an oxidation-resistant metal-based target material in such an amount as to enable the oxidation-resistant metal-based clusters to partially cover the anti-microbial metal-based clusters so as to permit exposure of at least a part of one of the anti-microbial metal-based clusters.

2. The method of claim 1, wherein the anti-microbial clusters are silver clusters.

3. The method of claim 2, wherein the metal-based target material is silver.

4. The method of claim 1, wherein the oxidation-resistant metal-based clusters are composed of a metal selected from the group consisting of Ti, Au, Pd, and Pt.

5. The method of claim 4, wherein the oxidation-resistant metal-based target material is composed of a material selected from the group consisting of Ti, Au, Pd, Pt, and alloys thereof.

6. The method of claim 3, wherein step (a) is carried out using a magnetron sputtering procedure under a pressure of 2×10⁻³ to 8×10⁻³ torr and a power density of 0.2 to 10 w/cm².

7. The method of claim 5, wherein step (b) is carried out using a magnetron sputtering procedure under a pressure of 2×10⁻³ to 8×10⁻³ torr and a power density of 2 to 17 w/cm².

8. An anti-microbial fabric prepared by a process comprising the following steps:
(a) depositing anti-microbial metal-based clusters on an outer surface of a fabric substrate by sputtering a metal-based target material which possesses anti-microbial activity and which is prone to oxidation upon air exposure; and
(b) depositing oxidation-resistant metal-based clusters on the outer surface of the fabric substrate by sputtering an oxidation-resistant metal-based target material in such an amount as to enable the oxidation-resistant metal-based clusters to partially cover the anti-microbial metal-based clusters so as to permit exposure of at least a part of one of the anti-microbial metal-based clusters.

9. The anti-microbial fabric of claim 8, wherein said anti-microbial clusters are silver clusters, and are present in an amount ranging from 10 to 2,000 ppm.

10. The anti-microbial fabric of claim 9, wherein said metal-based target material is silver.

11. The anti-microbial fabric of claim 8, wherein said oxidation-resistant metal-based clusters are composed of a metal selected from the group consisting of Ti, Au, Pd, and Pt.

12. The anti-microbial fabric of claim 11, wherein said oxidation-resistant metal-based target material is composed of a material selected from the group consisting of Ti, Au, Pd, Pt, and alloys thereof.

13. The anti-microbial fabric of claim 11, wherein each of said oxidation-resistant metal-based clusters has an average thickness ranging from 50 to 500 Å.
